(19) United States
(12) Patent Application Publication
(10) Pub. No.: US 2010/0181590 A1
(43) Pub. Date: Jul. 22, 2010

(54) LIGHT-EMITTING DIODE ILLUMINATING APPARATUS

(76) Inventor: Jen-Shyan Chen, Taiwan (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 12/666,058

(22) PCT Filed: Jun. 25, 2007
(86) PCT No.: PCT/CN2007/001982

§ 371 Date: Dec. 22, 2009

(51) Int. Cl. H01L 33/00

(52) U.S. Cl. 257/98; 257/E33.056; 257/E33.067

(57) ABSTRACT

The invention provides a light-emitting diode illuminating apparatus. The light-emitting diode illuminating apparatus includes a carrier, a substrate, a light-emitting diode die, and a micro-lens assembly. The carrier includes a top surface and a bottom surface. A first recess is formed on the top surface of the carrier. A second recess is formed on the bottom surface of the carrier. The first recess is connected to the second recess. The substrate is embedded into the second recess. The light-emitting diode die is disposed on the substrate. The micro-lens assembly is disposed above the light-emitting diode die.

### BACKGROUND OF THE INVENTION

1. Field of the Invention

The present invention relates to a light-emitting diode illuminating apparatus, and more particularly, relates to a light-emitting diode illuminating apparatus with a micro-lens assembly.

2. Description of the Prior Art

With the development of semi-conductor light emitting devices, a light-emitting diode (LED) which has several advantages, such as power save, seismic resistance, quick reaction, and so on, becomes a new light source. Therefore, LEDs are widely used as indicator lights on electronic devices, and the use of LEDs as light source of illumination products becomes a trend. In order to raise illumination, high-power LEDs are used as light source in the illumination products. Additionally, if light could not be converged effectively, it will result in being short of illumination. Hence in general application, more high-power LEDs are used for obtaining desired illumination, which results in other problems, for example, heat dissipation.

If light emitted by LEDs is not adjusted, it will be scatted everywhere, so that the light is not converged effectively. In the prior art, a lens or a convex is usually set on a LED to converge the light emitted by the LED. Additionally, the mentioned lens could be formed in the packing process of the LED dies. No matter which method is used, the beam angle of the light emitted from the lens may be 145 degrees and the light is hard to be converged thereby to satisfy with the requirement of illuminating.

Therefore, it is necessary to provide a light-emitting diode illuminating apparatus with a micro-lens assembly which could converge light effectively for solving the above-mentioned problem.

### SUMMARY OF THE INVENTION

A scope of the invention is to provide a light-emitting diode illuminating apparatus.

Another scope of the invention is to provide a light-emitting diode illuminating apparatus with a micro-lens assembly.

The light-emitting diode illuminating apparatus of the invention includes a carrier, a substrate, a light-emitting diode die, and a micro-lens assembly. The carrier includes a top surface and a bottom surface. A first recess is formed on the top surface of the carrier; a second recess is formed on the bottom surface of the carrier. The first recess is connected to the second recess. The substrate is embedded into the second recess. The light-emitting diode die is disposed on the substrate. The micro-lens assembly is disposed above the first recess.

The micro-lens assembly includes several protrusions which are distributed two-dimensionally on a surface of the micro-lens assembly. Each of the protrusions could be a hemispherical micro-lens, a cylindrical micro-lens or a pyramidal micro-lens. The protrusions could be several concentric circles and a section of each protrusion could be a semicircle, a triangle or a trapezoid. Additionally, the surface of the micro-lens assembly includes a first region and a second region. The number of the protrusions per unit area on the first region is larger than the number of the protrusions per unit area on the second region. It is not necessary to distribute the protrusions uniformly on the surface. In an embodiment, the beam angle of the light emitted from the micro-lens assembly could be below 20 degrees.

Additionally, the carrier is a low temperature co-fired ceramic board, a printed circuit board or a metal core circuit board. Then a glue could be filled between the substrate and the second recess for mounting the substrate in the second recess tightly. The substrate is made of silicon, metal or low temperature co-fired ceramics. The light-emitting diode die is a semiconductor light-emitting diode or a semiconductor laser. The light-emitting diode illuminating apparatus could further include a packaging material which is disposed between the light-emitting diode die and the micro-lens assembly and covers the light-emitting diode die.

Additionally, in an embodiment, a diameter of the first recess is smaller than a diameter of the second recess, so that the second recess includes an upper portion that the substrate is electrically connected to. In another embodiment, several circuit contacts are set on the substrate and else circuit contacts are correspondingly set on the upper portion. When the substrate is connected to the upper portion, the circuit contacts of the substrate are electrically connected to the circuit contacts of the upper portion. In another embodiment, the substrate includes a third recess and a reflection layer. The reflection layer is on the third recess and the light-emitting diode die is disposed in the third recess above the reflection layer.

The light-emitting diode illuminating apparatus of the invention could further include a heat-conducting device and a supporting member. The heat-conducting device includes a flat portion where the substrate is disposed. The supporting member is engaged to the heat-conducting device and the carrier is mounted on the supporting member. The heat-conducting device is a heat pipe or a heat-conducting column. A heat-conducting thermal phase change material could be disposed between the flat portion and the substrate. In an embodiment, the substrate includes a bottom surface, and the bottom surface of the substrate and the bottom surface of the carrier are coplanar substantially, so that the heat-conducting thermal phase change material could be filled between the flat portion and the substrate completely for preventing from generating gas holes.

Additionally, the heat-conducting thermal phase change material has stickiness and the substrate could be stuck on the heat-conducting device thereby. Moreover, the heat-conducting thermal phase change material has a phase transition temperature. When the phase of the heat-conducting thermal phase change material is changed, the mobility of the heat-conducting thermal phase change material will increase. It is more helpful to the material to be filled effectively between the substrate and the flat portion, so as to prevent from generating gas holes. Hence the heat generated by the light-emitting diode die in operation could be conducted to the heat-conducting device and then be dissipated more effectively. In an embodiment, the phase transition temperature is between 40 degrees Centigrade and 60 degrees Centigrade. Additionally, the heat-conducting thermal phase change material has a thermal conductivity and the thermal conductivity is between 3.6 W/mK and 4.0 W/mk.

Therefore, the light-emitting diode illuminating apparatus of the invention adjusts the light emitted by the light-emitting diode die through the micro-lens assembly, so that the light could be converged. Additionally, in order to provide effective illumination, the micro-lens assembly could reduce the beam angle of the light emitted from the micro-lens assembly through designing geometric shapes of the protrusions.

The advantage and spirit of the invention may be understood by the following recitations together with the appended drawings.

### BRIEF DESCRIPTION OF THE APPENDED DRAWINGS

FIG. 1A illustrates a partial cross section of a light-emitting diode illuminating apparatus according to a preferred embodiment of the invention.

FIG. 1B illustrates a partial explosion diagram of the light-emitting diode illuminating apparatus.

FIG. 1C illustrates a plan view of the micro-lens assembly of the light-emitting diode illuminating apparatus.

FIG. 1D illustrates another distribution of the protrusions of the micro-lens assembly.

FIG. 1E illustrates another distribution of the protrusions of the micro-lens assembly.

FIG. 2A illustrates geometrical shapes of the protrusions of the micro-lens assembly.

FIG. 2B illustrates another type of geometrical shapes of the protrusions of the micro-lens assembly.

FIG. 2C illustrates a cross section of the micro-lens assembly in FIG. 2B.

FIG. 2D illustrates another type of geometrical shapes of the protrusions of the micro-lens assembly.

FIG. 2E illustrates a cross section of the micro-lens assembly in FIG. 2D.

FIG. 2F illustrates another type of the cross section of the micro-lens assembly in FIG. 2D.

FIG. 3 illustrates a partial cross section of a light-emitting diode illuminating apparatus according to an embodiment of the invention.

### DETAILED DESCRIPTION OF THE INVENTION

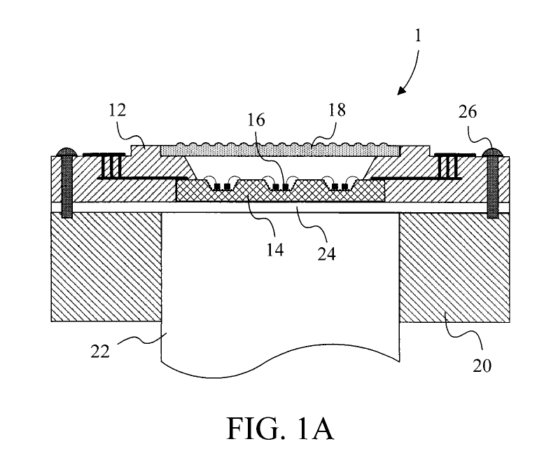

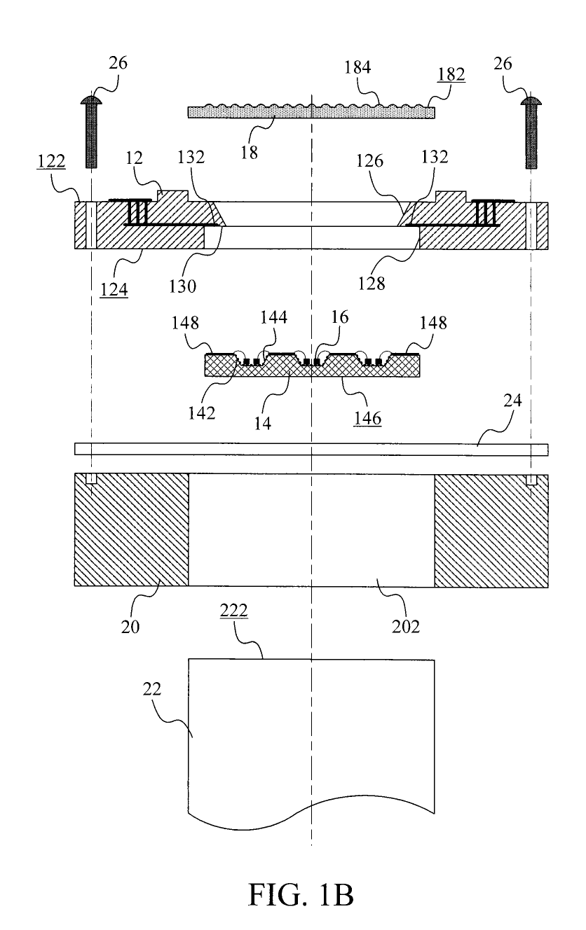

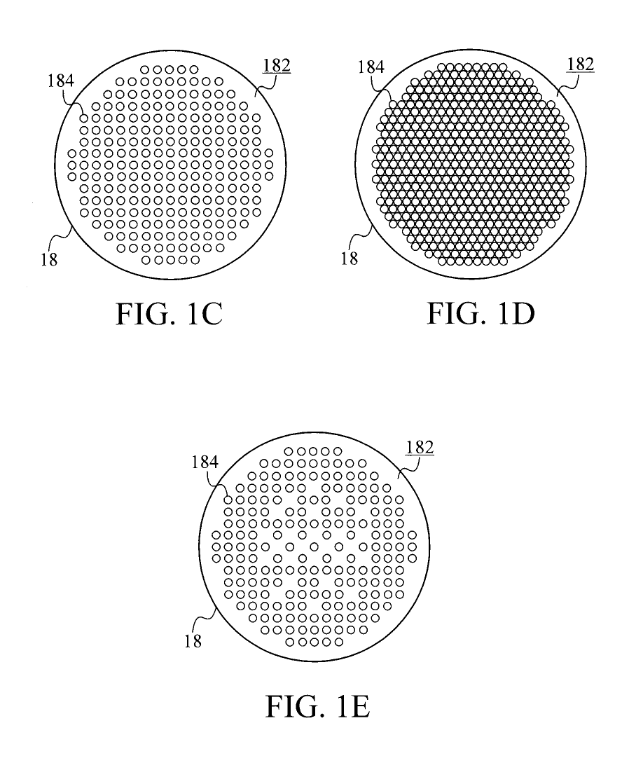

Please refer to FIG. 1A and FIG. 1B. FIG. 1A illustrates a partial cross section of a light-emitting diode illuminating apparatus 1 according to a preferred embodiment of the invention. FIG. 1B illustrates a partial explosion diagram of the light-emitting diode illuminating apparatus 1. The light-emitting diode illuminating apparatus 1 of the invention includes a carrier 12, a substrate 14, several light-emitting diode dies 16, a micro-lens assembly 18, a supporting member 20, a heat-conducting device 22 and a heat-conducting thermal phase change material 24.

The carrier 12 includes a top surface 122 and a bottom surface 124. A first recess 126 is formed on the top surface 122 of the carrier 12; a second recess 128 is formed on the bottom surface 124 of the carrier 12. The first recess 126 is connected to the second recess 128. The substrate 14 is embedded into the second recess 128 and includes several third recesses 142. A reflection layer 144 (represented as a dotted line) is formed on each of the third recesses. The light-emitting diode dies 16 are disposed in the third recesses 142 above the reflection layer 144. Additionally, a diameter of the first recess 126 at the place where the first recess 126 is connected to the second recess 128 is smaller than a diameter of the second recess 128 at the place where the second recess 128 is connected to the first recess 126, so that the second recess 128 includes an upper portion 130 where the substrate 14 is connected. The upper portion 130 is able to stop the substrate 14 and the attached area between the substrate 14 and the second recess 128 will increase thereby (therefore, the substrate 14 is attached on the second recess 128 tightly). If a glue is filled between the substrate 14 and the second recess 128, the substrate 14 will be mounted on the second recess 128 tighter. Additionally, several circuit contacts 148 could be set on the substrate 14 and else circuit contacts 132 could be correspondingly set on the upper portion 130. When the substrate 14 is connected to the upper portion 130, the circuit contacts 148 of the substrate 14 are electrically connected to the circuit contacts 132 of the upper portion 130. In such situation, the light-emitting diode dies 16 are electrically connected to the substrate 14 instead of being wire bonded to the carrier 12.

The micro-lens assembly 18 includes several protrusions 184. The several protrusions 184 are distributed two-dimensionally on a surface 182 of the micro-lens assembly 18. Each of the protrusions 184 is a hemisphere. A plane view of the micro-lens assembly 18 is shown in FIG. 1C. The distribution of the protrusions 184 is not limited to FIG. 1C and it may be arranged as shown in FIG. 1D (the most closed-arrangement). Although the protrusions 184 of FIG. 1C and FIG. 1D are distributed uniformly on the surface 182, the distribution of the protrusions 184 of the invention is not limited to these. For example, the distribution of the protrusions 184 may be closed in some regions and dispersed in other regions. It depends on the setting of products. For example, the distribution density of the protrusions 184 (the number of the protrusions 184 per unit area) are higher near the circumference of the surface 182 and lower near the center of the surface 182, as shown in FIG. 1E.

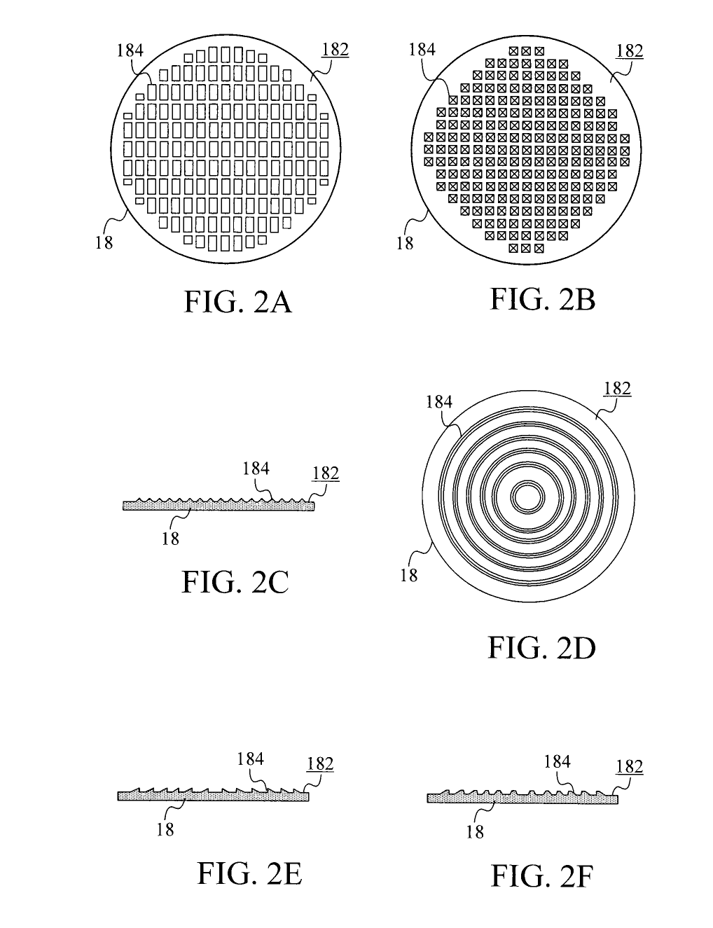

In practical application, the protrusions 184 could be a cylindrical micro-lens (as shown in FIG. 2A) or a pyramidal micro-lens (as shown in FIG. 2B) but not limited to the above-mentioned cases. A cross section of FIG. 2A could refer to FIG. 1B. The cross section of FIG. 2B is shown in FIG. 2C. Additionally, the protrusions 184 could be arranged to form several concentric circles or the protrusions are several concentric circles as shown in FIG. 2D. A section of each protrusion is a semicircle (as shown in FIG. 1B), a triangle (as shown in FIG. 2E) or a trapezoid (as shown in FIG. 2F). Each of the protrusions 184 could be different from others and the geometrical shapes of the protrusions 184 could be a combination of the above-mentioned shapes. The description of the protrusions 184 in the preferred embodiment is also applied here. Additionally, the sizes of the protrusions as well as the number of the protrusions are not limited to the appended drawings. The protrusions 184 could be formed on the micro-lens assembly 18 toward to the light-emitting diode dies 16.

Please refer to FIG. 1A and FIG. 1B. According to the preferred embodiment, the supporting member 20 has a hole 202, so that the supporting member 20 could be mounted on the heat-conducting device 22. The heat-conducting device 22 includes a flat portion 222, the heat-conducting thermal phase change material 24 is disposed on the flat portion 222, and then the substrate 14 is disposed on the heat-conducting thermal phase change material 24. The heat-conducting thermal phase change material 24 could be filled with the gap between the substrate 14 and the flat portion 222 so as to reduce the interface thermal resistance between the substrate 14 and the flat portion 222. Because the substrate 14 has been embedded into the second recess 128, the mounting of the substrate 14 could be achieved by mounting the carrier 12. The carrier 12 is mounted on the supporting member 20 by several screws, so that the heat-conducting thermal phase change material 24 is compressed by the substrate 14 for being mounted the flat portion 222. Because a bottom surface 146 of the substrate 14 and the bottom surface 124 of the carrier 12 are coplanar substantially, the heat-conducting thermal phase change material 24 could be filled between the substrate 14 and the flat portion 222 completely. What is remarkable is that the heat-conducting thermal phase change material 24 does not have to be filled between the carrier 12 and the supporting member 20.

According to the preferred embodiment, the heat-conducting thermal phase change material 24 has a phase transition temperature and the phase transition temperature is between 40 degrees centigrade and 60 degrees centigrade but not limited to it. After the phase of the heat-conducting thermal phase change material 24 is changed, the mobility of the heat-conducting thermal phase change material 24 will increase. It is not only useful for the material 24 to be filled between the substrate 14 and the flat portion 222, so as to prevent from generating gas cells but also beneficial to conduct heat which is generated by the light-emitting diode dies 16 in an operation process to the heat-conducting device 22, so as to dissipate the heat. Additionally, the heat-conducting thermal phase change material 24 has a thermal conductivity and the thermal conductivity is between 3.6 W/mK and 4.0 W/mk. Moreover, the heat-conducting thermal phase change material 24 has stickiness and it is useful for mounting the substrate 14 on the flat portion 222. The heat-conducting device 22 could include several fins (not shown in figure) for dissipating heat conducted from the flat portion 222. The installation of the fins depends on design of production.

It is added that the method of mounting the carrier 12 by the supporting member 20 is not limited to the method as shown in FIG. 1A. For example, the supporting member 20 could wedge the carrier 12 structurally. Of course, it allows of combining the above-mentioned two methods to mount the carrier 12. The light-emitting diode illuminating apparatus 1 further includes a packaging material (not shown in figure) which is disposed between the light-emitting diode die 16 and the micro-lens assembly 18 and covers the light-emitting diode die 16. However, it is not necessary to fill the first recess 126 completely with the packaging material. Additionally, the carrier 12 according to the invention is a low temperature co-fired ceramic board, a printed circuit board, a metal core circuit board, or other material capable of being engaged to the substrate 14. The substrate 14 could be made of silicon, metal, low temperature co-fired ceramics, or other material capable of bearing the light-emitting diode die 16. The light-emitting diode die 16 is a semiconductor light-emitting diode or a semiconductor laser and the heat-conducting device 22 is a heat pipe, a heat-conducting column or other devices capable of conducting heat.

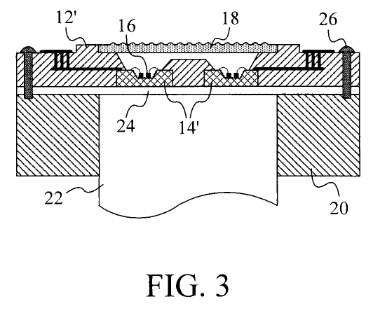

Although the preferred embodiment only includes one substrate 14, the quantity of substrates 14 of the invention is not limited to one. Please refer to FIG. 3. In an embodiment, the carrier 12′ could include several the second recesses 128 (not labeled in FIG. 3), a substrate 14′ is embedded into each of the second recesses 128, and at least one light-emitting diode die 16 is disposed on each of the substrates 14′.

To sum up, the light-emitting diode illuminating apparatus of the invention adjusts light emitted by the light-emitting diode die through the micro-lens assembly, so that the light could be converged. Additionally, the micro-lens assembly could reduce beam angle of the light emitted from the micro-lens assembly for illuminating effectively through the design of the protrusions of the apparatus. The power for the high-power light-emitting diode dies is therefore saved. Additionally, the light-emitting diode illuminating apparatus uses the heat-conducting thermal phase change material to stick the substrate on the flat portion. After the phase of the heat-conducting thermal phase change material is changed, the mobility of the heat-conducting thermal phase change material will increase. It is useful for the heat-conducting thermal phase change material to be filled between the substrate and the flat portion. Even if the heat-conducting thermal phase change material is used for a long time, the mobility and conductivity of the heat-conducting thermal phase change material are still maintained, so that the interface thermal resistance between the substrate and the heat-conducting device does not increase and the service time of the light-emitting diode illuminating apparatus of the invention is longer than that of a traditional light-emitting diode illuminating apparatus.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A light-emitting diode illuminating apparatus comprising:
a carrier comprising a top surface and a bottom surface, a first recess being formed on the top surface of the carrier, a second recess being formed on the bottom surface of the carrier, the first recess being connected to the second recess;
a substrate embedded into the second recess;
a light-emitting diode die disposed on the substrate; and
a micro-lens assembly disposed above the first recess.

2. The light-emitting diode illuminating apparatus of claim 1, wherein the micro-lens assembly comprises a plurality of protrusions distributed two-dimensionally on a surface of the micro-lens assembly.

3. The light-emitting diode illuminating apparatus of claim 2, wherein each of the protrusions is a hemispherical micro-lens, a cylindrical micro-lens or a pyramidal micro-lens.

4. The light-emitting diode illuminating apparatus of claim 2, wherein the protrusions are a plurality of concentric circles.

5. The light-emitting diode illuminating apparatus of claim 4, wherein a section of each protrusion is a semicircle, a triangle or a trapezoid.

6. The light-emitting diode illuminating apparatus of claim 2, wherein the surface of the micro-lens assembly comprises a first region and a second region and a number of the protrusions per unit area on the first region is larger than a number of the protrusions per unit area on the second region.

7. The light-emitting diode illuminating apparatus of claim 1, wherein the carrier is a low temperature co-fired ceramic board, a printed circuit board or a metal core circuit board.

8. The light-emitting diode illuminating apparatus of claim 1, wherein a glue is filled between the substrate and the second recess.

9. The light-emitting diode illuminating apparatus of claim 1, wherein a diameter of the first recess is smaller than a diameter of the second recess, so that the second recess comprises an upper portion connected to the substrate.

10. The light-emitting diode illuminating apparatus of claim 9, wherein the substrate is electrically connected to the upper portion.

11. The light-emitting diode illuminating apparatus of claim 1, wherein the substrate comprises a third recess and the light-emitting diode die is disposed in the third recess.

12. The light-emitting diode illuminating apparatus of claim 11, wherein the substrate comprises a reflection layer on the third recess and the light-emitting diode die is disposed on the reflection layer.

13. The light-emitting diode illuminating apparatus of claim 1, further comprising a heat-conducting device, the heat-conducting device comprising a flat portion, the substrate being disposed on the flat portion.

14. The light-emitting diode illuminating apparatus of claim 13, wherein the substrate comprises a bottom surface and the bottom surface of the substrate and the bottom surface of the carrier are coplanar substantially.

15. The light-emitting diode illuminating apparatus of claim 13, wherein the heat-conducting device is a heat pipe or a heat-conducting column.

16. The light-emitting diode illuminating apparatus of claim 13, further comprising a supporting member, the supporting member being engaging to the heat-conducting device, the carrier being mounted on the supporting member.

17. The light-emitting diode illuminating apparatus of claim 13, further comprising a heat-conducting thermal phase change material, the heat-conducting thermal phase change material being disposed between the flat portion and the substrate.

18. The light-emitting diode illuminating apparatus of claim 17, wherein the heat-conducting thermal phase change material has stickiness.

19. The light-emitting diode illuminating apparatus of claim 17, wherein the heat-conducting thermal phase change material has a phase transition temperature and the phase transition temperature is between 40 degrees centigrade and 60 degrees centigrade.

20. The light-emitting diode illuminating apparatus of claim 17, wherein the heat-conducting thermal phase change material has a thermal conductivity and the thermal conductivity is between 3.6 W/mK and 4.0 W/mk.

21. The light-emitting diode illuminating apparatus of claim 1, further comprising a packaging material, the packaging material being disposed between the light-emitting diode die and the micro-lens assembly and covering the light-emitting diode die.

22. The light-emitting diode illuminating apparatus of claim 1, wherein the substrate is made of silicon, metal, or low temperature co-fired ceramics.

23. The light-emitting diode illuminating apparatus of claim 1, wherein the light-emitting diode die is a semiconductor light-emitting diode or a semiconductor laser.
